(19) United States
(12) Patent Application Publication
(10) Pub. No.: US 2011/0073153 A1
(43) Pub. Date: Mar. 31, 2011

(54) PHOTOVOLTAIC DEVICE AND MANUFACTURING METHOD THEREOF

(75) Inventor: Mitsuhiro Matsumoto, Gifu-shi (JP)

(73) Assignee: SANYO ELECTRIC CO., LTD., Moriguchi-shi (JP)

(21) Appl. No.: 12/890,781

(22) Filed: Sep. 27, 2010

(30) Foreign Application Priority Data
Sep. 28, 2009 (JP) 2009-222254
Aug. 30, 2010 (JP) 2010-191817

(51) Int. Cl. H01L 31/042; H01L 31/18

(52) U.S. Cl. 136/244; 438/73; 257/E31.11

(57) ABSTRACT

In a structure in which a plurality of structures, having a transparent electrode, a photovoltaic unit, and a backside electrode sequentially layered over a transparent substrate, are connected in series, a insulating groove is formed in a panel periphery in a direction intersecting the direction of series connection in which the transparent electrode, the photovoltaic unit, and the backside electrode are removed, and a separating groove is formed in a region near the separating groove and parallel to the separating groove in which the transparent electrode is left and at least the backside electrode is removed.

### CROSS-REFERENCE TO RELATED APPLICATIONS

The entire disclosure of Japanese Patent Applications No. 2009-222254 filed on Sep. 28, 2009 and 2010-191817 filed on Aug. 30, 2010, including specification, claims, drawings, and abstract, is incorporated herein by reference in its entirety.

### BACKGROUND

1. Technical Field

The present invention relates to a photovoltaic unit and a manufacturing method of a photovoltaic unit.

2. Background Art

Solar cells are known which use polycrystalline, microcrystalline, or amorphous silicon. In particular, a solar cell having a structure in which thin films of microcrystalline or amorphous silicon are layered has attracted much attention in view of reduced resource consumption, cost reduction, and improved efficiency.

FIG. 2 is a cross sectional schematic view showing a basic structure of a photovoltaic device 100. The photovoltaic device 100 generally has a structure in which a transparent electrode 12, a photovoltaic unit 14, and a backside electrode 16 are layered over a transparent substrate 10 such as glass, and generates electric power by allowing light to enter through the transparent substrate 10. A manufacturing method and a patterning device for integrating such photovoltaic devices in series are known (for example, in Patent Literature 1).

FIGS. 3A-3F show a manufacturing process of the photovoltaic device 100 in the related art. In FIGS. 3A-3F, a plan view and cross sectional views are schematically shown for each step of the manufacturing process of the photovoltaic device 100. The cross sectional views show cross sections along a line A-A in the plan view and cross sections along a line B-B in the plan view.

In step S10, as shown in FIG. 3A, a slit S1 which divides the transparent electrode 12 formed over the transparent substrate 10 is formed through laser patterning and a slit S2 is formed through laser patterning in a direction perpendicular to the slit S1. In step S12, as shown in FIG. 3B, the photovoltaic unit 14 is formed covering the transparent electrode 12. As the photovoltaic unit 14, an amorphous silicon (a-Si) photovoltaic unit, a microcrystalline (μc-Si) photovoltaic unit, or a tandem structure of these photovoltaic units may be employed. In step S14, as shown in FIG. 3C, a slit S3 which divides the photovoltaic unit 14 is formed through laser patterning at a position near the slit S1 and not overlapping the slit S1, and along a direction of the slit S1. In step S16, as shown in FIG. 3D, the backside electrode 16 is formed covering the photovoltaic unit 14. In step S18, as shown in FIG. 3E, a slit S4 which divides the photovoltaic unit 14 and the backside electrode 16 is formed through laser patterning at a position near the slit S3 and not overlapping the slits S1 and S3, and along the direction of the slits S1 and S3. With this process, a structure in which a plurality of photovoltaic cells are connected in series along the direction of the slit S2 is obtained. In step S20, as shown in FIG. 3F, a slit S5 which divides the photovoltaic unit 14 and the backside electrode 16 formed in the slit S2 is formed through laser patterning.

In this manner, photovoltaic cells adjacent in the direction of the slit S1 are electrically separated from each other, and a structure is obtained in which a plurality of photovoltaic cell groups, each including a plurality of photovoltaic cells connected in series, are aligned. The photovoltaic cell groups are finally connected in parallel to each other, and the photovoltaic device 100 is formed.

In addition, in step S20, the slit S5 is also formed as an insulating groove 18 in a panel periphery of the photovoltaic device 100, to electrically insulate the outside and a panel end of the photovoltaic device 100 from each other.

A technique is also known in which an end of the backside electrode 16 of the photovoltaic device 100 is placed at a more inward position of the panel than an end of the photovoltaic unit 14, to improve the insulating characteristic at the panel periphery of the photovoltaic device 100.

In the thin film solar cells of the related art, when the thin film solar cell is used outdoors, there may be cases where moisture enters from a sealing portion of the end of the photovoltaic device 100, causing, in the structure where the insulating groove 18 and the backside electrode 16 are placed at inner positions, reduction of electrical insulation at the panel periphery, detachment of the photovoltaic unit 14, or formation of a short-circuiting path due to contact between the transparent electrode 12 and the backside electrode 16.

In order to secure sufficient electrical insulation at the panel periphery, the laser power when the slit S5 is formed must be set at a high power. However, such a configuration may cause damage in the end surface of the photovoltaic unit 14, possibly resulting in a short-circuiting path. In addition, in the case of a small-size solar cell which is used for indoor light and in which the possibility of moisture intrusion is low, such a solar cell is formed with a large-area substrate and then cutting the substrate into a predetermined size. During this process, the transparent electrode 12 and the backside electrode 16 at the end of each photovoltaic device 100 may contact each other at the cut surface, resulting in a short-circuiting path. Therefore, the slits S2 and S5 must be formed, resulting in a reduction of effective area for power generation.

### SUMMARY

According to one aspect of the present invention, there is provided a photovoltaic device wherein a plurality of photovoltaic cells in which a first electrode, a power generation layer, and a second electrode are sequentially layered over a substrate are connected in series, and the photovoltaic device comprises ends of the power generation layer and the second electrode at a periphery of the photovoltaic device and extending in a direction of the series connection, and an insulating groove formed in a region near a insulating groove the ends and parallel to the ends and formed by leaving the first electrode and removing at least the second electrode.

According to another aspect of the present invention, there is provided a method of manufacturing a photovoltaic device, comprising forming a plurality of photovoltaic cells, in which a first electrode, a power generation layer, and a second electrode are sequentially layered over a substrate, in series connection to each other, forming a separating groove at a periphery of the photovoltaic device in a direction intersecting the direction of the series connection by removing the first electrode, the power generation layer, and the second electrode, and forming an insulating groove in a region near the separating groove and parallel to the separating groove by leaving the first electrode and removing at least the second electrode.

### BRIEF DESCRIPTION OF THE DRAWINGS

A preferred embodiment of the present invention will be described in detail based on the following drawings, wherein:

FIG. 1A is a plan view and cross sectional views showing a manufacturing process of a photovoltaic device according to a preferred embodiment of the present invention;

FIG. 1B is a plan view and cross sectional views showing the manufacturing process of the photovoltaic device according to the preferred embodiment of the present invention;

FIG. 1C is a plan view and cross sectional views showing the manufacturing process of the photovoltaic device according to the preferred embodiment of the present invention;

FIG. 1D is a plan view and cross sectional views showing the manufacturing process of the photovoltaic device according to the preferred embodiment of the present invention;

FIG. 1E is a plan view and cross sectional views showing the manufacturing process of the photovoltaic device according to the preferred embodiment of the present invention;

FIG. 2 is a cross sectional view showing a basic structure of a photovoltaic device;

FIG. 3A is a plan view and cross sectional views showing a manufacturing process of a photovoltaic device of related art;

FIG. 3B is a plan view and cross sectional views showing the manufacturing process of the photovoltaic device of related art;

FIG. 3C is a plan view and cross sectional views showing the manufacturing process of the photovoltaic device of related art;

FIG. 3D is a plan view and cross sectional views showing the manufacturing process of the photovoltaic device of related art;

FIG. 3E is a plan view and cross sectional views showing the manufacturing process of the photovoltaic device of related art;

FIG. 3F is a plan view and cross sectional views showing the manufacturing process of the photovoltaic device of related art;

FIG. 4 is a diagram showing an example structure of a photovoltaic device according to a preferred embodiment of the present invention;

FIG. 5 is a diagram showing a power generation characteristic of a photovoltaic device;

FIG. 6 is a diagram showing an equivalent circuit of the photovoltaic device shown in FIG. 4;

FIG. 7 is a diagram showing a relationship of a power generation output with respect to a distance between slits S5 and S6 of a photovoltaic device;

FIG. 8 is a diagram showing a relationship of a power generation output with respect to a distance between the slits S5 and S6 of a photovoltaic device; and

FIG. 9 is a diagram showing a relationship of a power generation output with respect to a distance between the slits S5 and S6 of a photovoltaic device.

### DESCRIPTION OF EMBODIMENTS

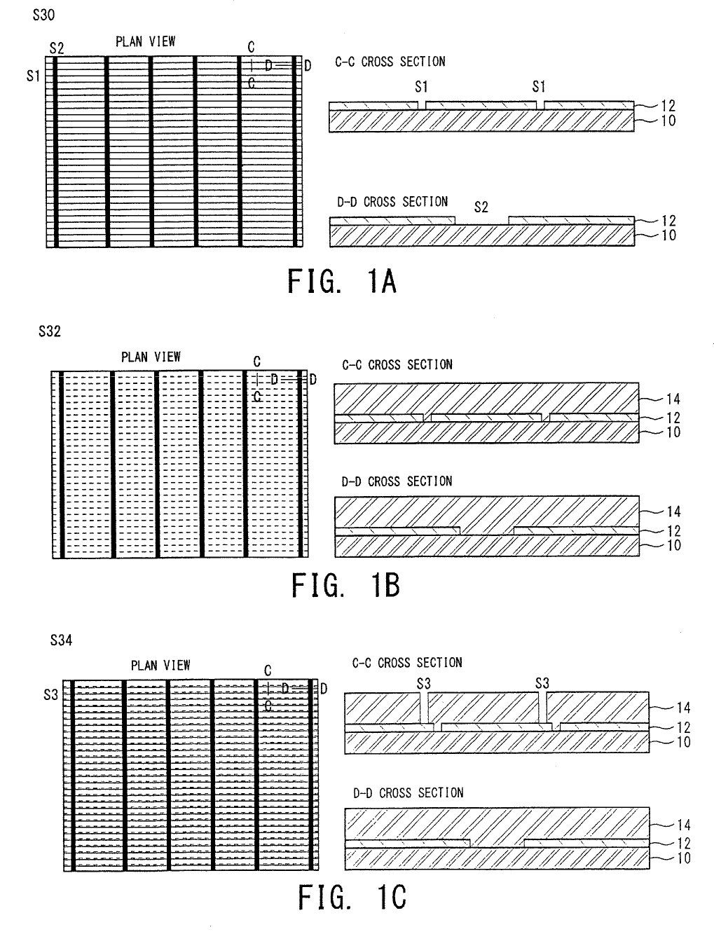

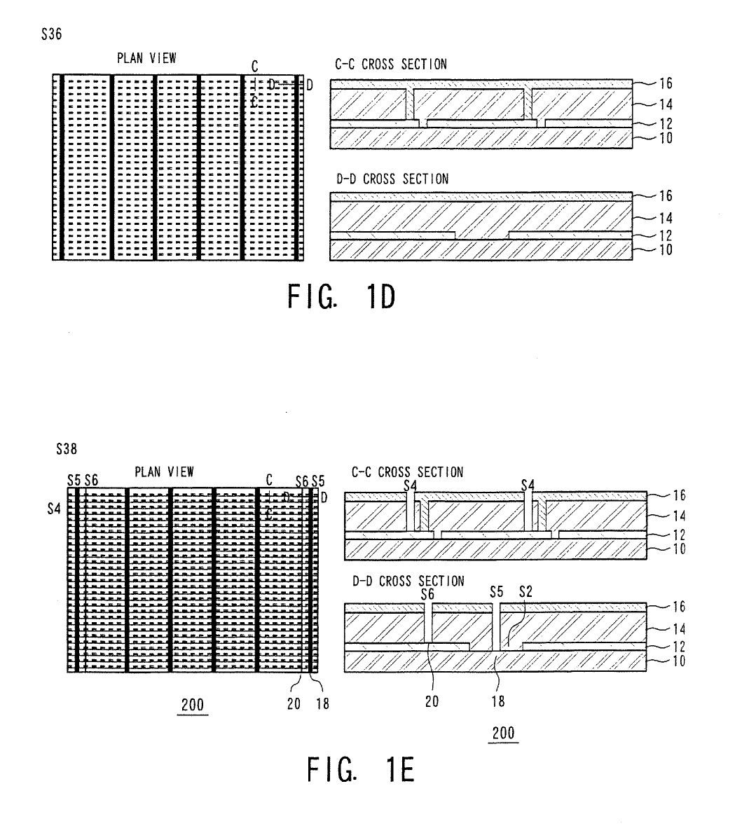

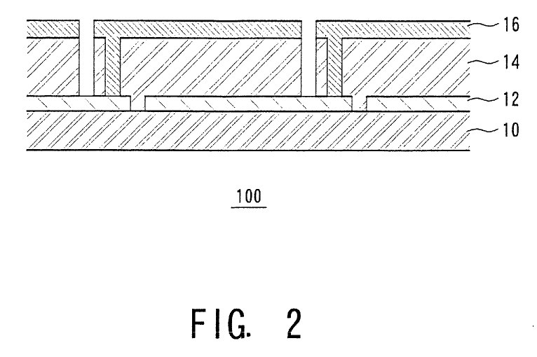

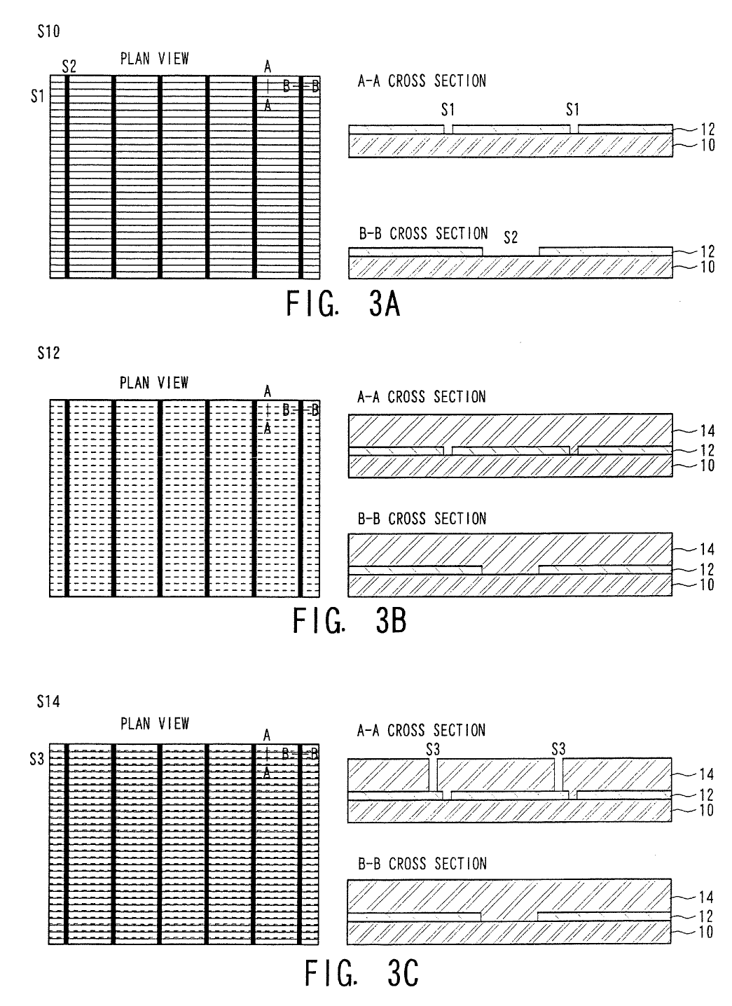

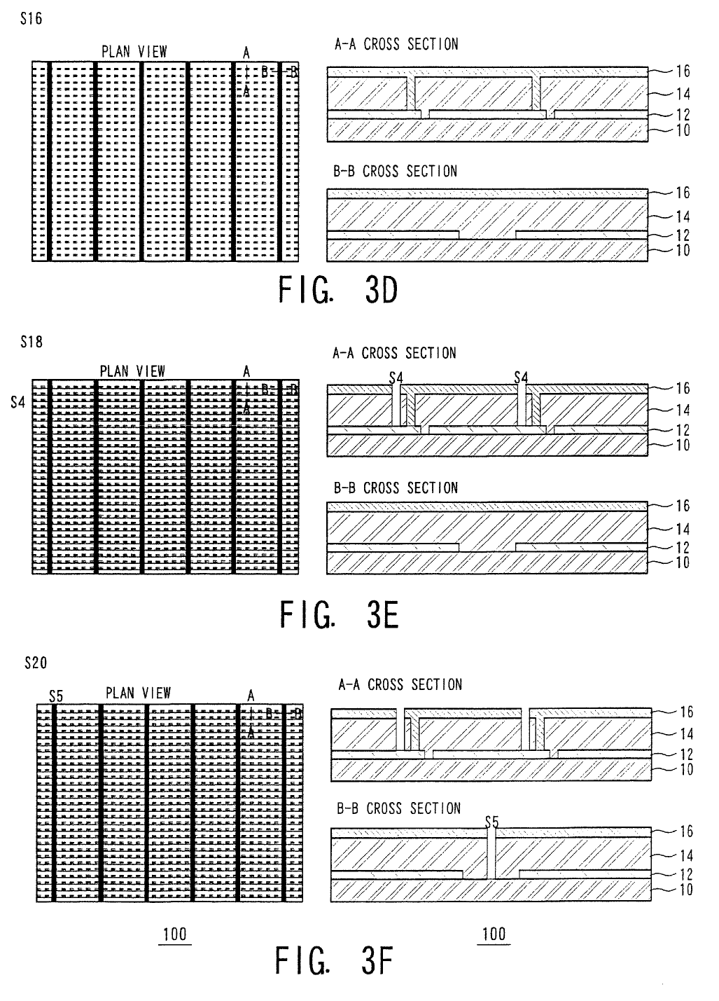

FIGS. 1A-1E show a manufacturing process of a photovoltaic device 200 according to a preferred embodiment of the present invention. FIGS. 1A-1E schematically show plan views and cross sectional views in the steps of the manufacturing process of the photovoltaic device 200. The cross sectional views show cross sections along a line C-C in the plan views and cross sections along a line D-D in the plan views.

In step S30, as shown in FIG. 1A, a slit S1 (in the left and right direction in the figure) which divides a transparent electrode 12 formed over a transparent substrate 10 is formed through laser patterning, and a slit S2 (in the up and down direction in the figure) is formed in a direction perpendicular to the slit S1. In this process, the slit S2 which becomes a insulating groove 18 is also formed in a panel periphery of the photovoltaic device 200.

For the transparent substrate 10, a material which transmits light of a wavelength used in photovoltaic in the solar cell is used, such as, for example, glass, plastic, etc. For the transparent electrode 12, a transparent conductive oxide in which tin (Sn), antimony (Sb), fluorine (F), aluminum (Al), or the like is doped into tin oxide (SnO₂), zinc oxide (ZnO), indium tin oxide (ITO), or the like may be used.

A laser device for forming the slits S1 and S2 preferably uses a YAG laser of a wavelength of 1064 nm. A laser beam emitted from the laser device is irradiated from the side of the transparent electrode 12 while the power of the laser beam is adjusted, and is continuously scanned in the direction of the slit S1 and the direction of the slit S2 which is perpendicular to the direction of the slit S1, so that the slits S1 and S2 can be formed. The laser for forming the slits S1 and S2 may alternatively be irradiated from the side of the transparent substrate 10.

Because a large number of slits S1 must be formed in order to integrate a large number of photovoltaic cells in series, it is preferable to use a multi-emission laser device in which a plurality of laser beam emission outlets are placed at equal distances along the direction perpendicular to the slit S1. For example, a laser device in which 2-5 laser beam emission outlets are placed is preferably used. With this process, a large number of slits S1 for integrating a large number of photovoltaic cells in series can be quickly formed. Because a size of the slit S2 may be larger than the sizes of the other slits and the patterning precision of the slit S2 may be lower than the other slits, the setting of the patterning conditions is simple even if the multi-emission laser device is used.

In step S32, as shown in FIG. 1B, a photovoltaic unit 14 is formed covering the transparent electrode 12 and the slits S1 and S2. The photovoltaic unit 14 is not particularly limited, and may be, for example, an amorphous silicon (a-Si) photovoltaic unit, a microcrystalline (μc-Si) photovoltaic unit, or a tandem structure of these photovoltaic units. The photovoltaic unit 14 can be formed using plasma CVD or the like.

In step S34, as shown in FIG. 1C, a slit S3 which divides the photovoltaic unit 14 is formed through laser patterning. The slit S3 is formed at a position near the slit S1 and not overlapping the slit S1, along the direction of the slit S1, and towards a surface of the transparent electrode 12.

For a laser device for forming the slit S3, a YAG laser (second harmonic) of a wavelength of 532 nm is preferably used. A laser beam emitted from the laser device is irradiated from the side of the transparent substrate 10 while the power of the laser beam is adjusted, and is scanned in the direction of the slit S3, so that the slit S3 can be formed.

In step 36, as shown in FIG. 1D, a backside electrode 16 is formed covering the photovoltaic unit 14 and the slit S3. The backside electrode 16 is preferably made of a reflective metal. Alternatively, the backside electrode 16 may have a layered structure of the reflective metal and a transparent conductive oxide (TCO). For the metal electrode, silver (Ag), aluminum (Al), or the like may be used. For the transparent conductive oxide (TCO), tin oxide (SnO₂), zinc oxide (ZnO), indium tin oxide (ITO), or the like may be used.

In step S38, as shown in FIG. 1E, slits S4, S5, and S6 which divide the photovoltaic unit 14 and the backside electrode 16 are formed through laser patterning. The slit S4 is formed at a position near the slit S3 and not overlapping slits S1 and S3, along the direction of the slits S1 and S3, and to a surface of the transparent electrode 12 in a manner to divide the photovoltaic unit 14 and the backside electrode 16. With this configuration, a structure is obtained in which a plurality of photovoltaic cells are connected in series along the direction of the slit S2.

The slit S5 is formed in a region where the slit S2 is formed, to the surface of the transparent electrode 12 in a manner to divide the photovoltaic unit 14 and the backside electrode 16 formed in the slit S2. Because the slit S5 is formed in a direction of the series connection, the photovoltaic cells adjacent in the direction of the slit S1 are electrically separated from each other. In addition, the slit S5 is also formed in the slit S2 formed at the panel periphery of the photovoltaic device 200 and which becomes the separating groove 18, to electrically separate the photovoltaic unit 14 and the backside electrode 16 at the panel periphery and the photovoltaic unit 14 and the backside electrode 16 at the inner side of the panel from each other.

Because the slit S5 is formed in the region where the slit S2 is formed, the irradiation of laser light from the side of the transparent electrode 12 is enabled, and when the slit S4 is formed, the slit S5 is formed continuously.

Further, the slit S6 is formed. The slit S6 becomes a separating groove 20. The slit S6 is formed by removing at least the backside electrode 16 and leaving only the transparent electrode 12 in a region further inward in the panel than the separating groove 18. For example, the slit S6 is formed by removing the photovoltaic unit 14 and the backside electrode 16 and leaving only the transparent electrode 12. In addition, the slit S6 is preferably formed parallel to the slits S2 and S5 which become the separating groove 18.

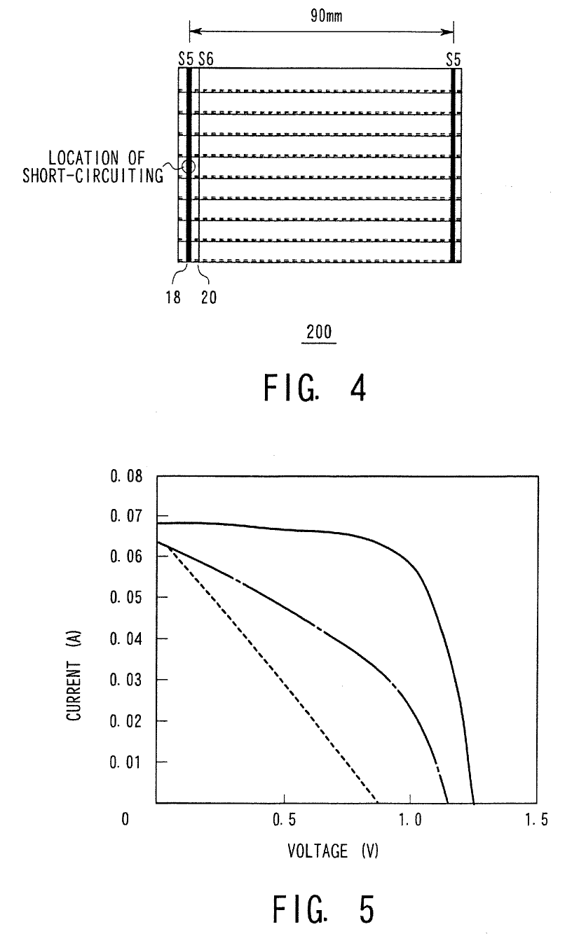

Next, a preferable position of the slit S6 of the photovoltaic device 200 is determined. FIG. 4 shows a structure of a photovoltaic panel formed for determining a preferable position of the slit S6 of the photovoltaic device 200. In the example configuration of FIG. 4, a length of the photovoltaic cell having a tandem structure of an amorphous silicon (a-Si) photovoltaic unit and a microcrystalline silicon (μc-Si) photovoltaic unit as the photovoltaic unit 14 is 90 mm, and 9 stages of arrays of the photovoltaic cells are formed.

FIG. 5 shows an actual measurement value of a power generation characteristic of the photovoltaic device 200 with respect to a distance between the slits S5 and S6. A wide solid line represents an initial power generation characteristic of 1 stage of the photovoltaic cells when the slit S6 is formed at a position distanced from the slit S5 by 5 mm. A dot-and-chain line represents an initial power generation characteristic of 1 stage of the photovoltaic cells when the slit S6 is formed at a position distanced from the slit S5 by 5 mm and the slit S5 is completely electrically short-circuited. A dotted line represents an initial power generation characteristic of 1 stage of the photovoltaic cells when the slit S6 is not formed (that is, a structure corresponding to a structure in which the slit S6 is formed at a position distanced from the slit S5 by 90 mm), and the slit S5 is completely electrically short-circuited.

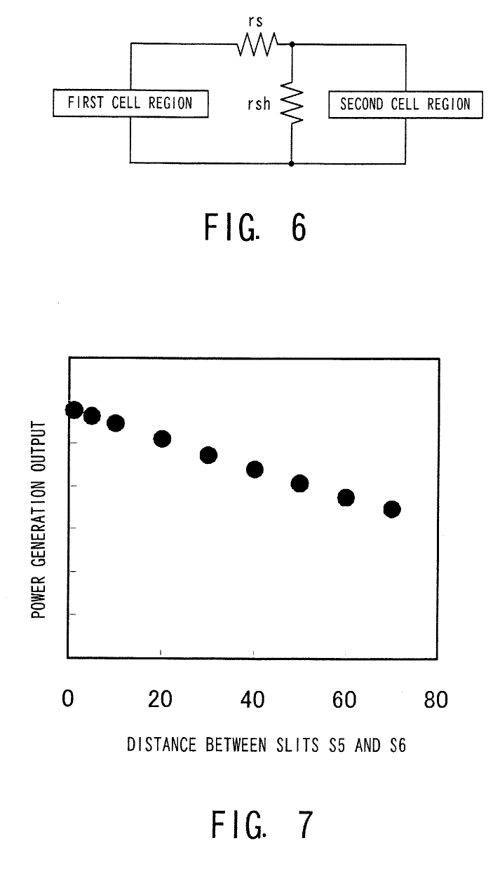

As shown in FIG. 6, an equivalent circuit of the photovoltaic device 200 of FIG. 4 is represented as a structure in which 1 stage of the photovoltaic cells is divided into a first cell region and a second cell region with an area ratio of 85:5 by the slit S6, and the first and second cell regions are connected by a series resistance rs and a parallel resistance rsh. In consideration of this, fitting is executed on the power generation characteristic of FIG. 5 with the series resistance rs of the equivalent circuit of FIG. 6 fixed and the parallel resistance rsh of the equivalent circuit of FIG. 6 being set as a parameter, and the parallel resistance rsh is determined for a case where the slit S6 is formed at a position distanced from the slit S5 by 5 mm and a case where the slit S6 is not formed. The parallel resistance rsh with respect to the distance from the slit S5 is then determined assuming that the parallel resistance rsh changes exponentially with respect to the distance from the slit S5, as shown by the following equation (1).

rsh=Aexp(−Bx) [Equation 1]

wherein A and B are coefficients.

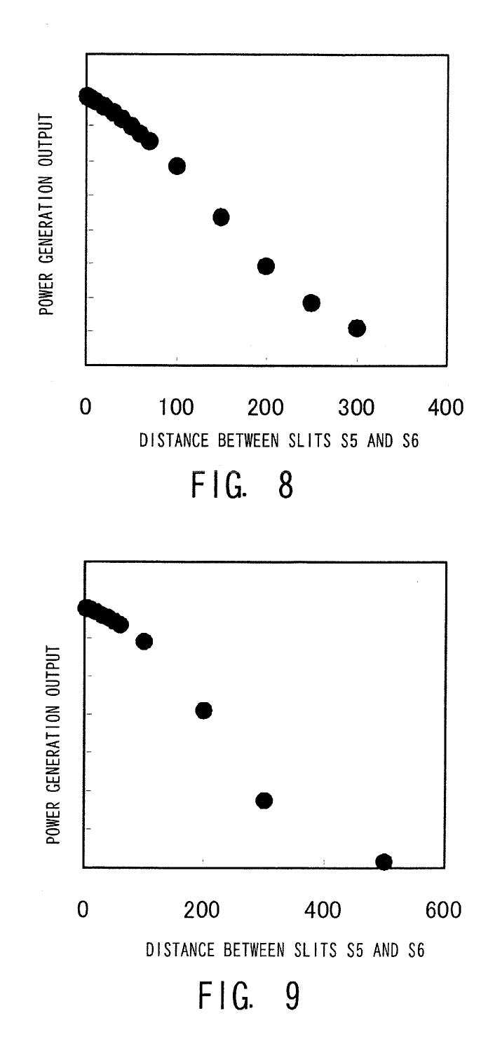

The parallel resistance rsh determined through the above-described method is applied to the equivalent circuit shown in FIG. 6, and a change of the power generation output with respect to the distance of the slit S6 from the slit S5 is calculated for cases where the length of the photovoltaic cell is 90 mm, 300 mm, and 600 mm. FIG. 7 shows the change of the power generation output when the length of the photovoltaic cell is 90 mm, FIG. 8 shows the change of the power generation output when the length of the photovoltaic cell is 300 mm, and FIG. 9 shows the change of the power generation output when the length of the photovoltaic cell is 600 mm.

As shown in FIGS. 8 and 9, the power generation output of the photovoltaic device 200 gradually decreases up to the distance of the slit S6 from the slit S5 of approximately 100 mm, the slope of reduction becomes steep after the distance exceeds 100 mm, and the slope again becomes gradual as the distance becomes larger. Therefore, the slit S6 (second insulating grove 20) is preferably formed in a range in which the power generation output of the photovoltaic device 200 is not rapidly reduced, that is, in a region within 100 mm from the slit S5 (separating groove 18). In particular, the slit S6 is preferably formed in a region near the slit S5 in which short-circuiting tends to occur, that is, in a region within 10 mm from the slit S5.

For a laser device for forming the slits S4, S5, and S6, a YAG laser (second harmonics) of a wavelength of 532 nm is preferably used. A laser beam emitted from the laser device is irradiated from the side of the transparent substrate 10 while the power of the laser beam is adjusted, and is scanned in the directions of the slits S4, S5, and S6, so that the slits S4, S5, and S6 can be formed.

As described above, the slits S1, S3, and S4 are formed to connect adjacent photovoltaic cells in series, and the slits S2 and S5 are formed to align the photovoltaic cell groups, in which the photovoltaic cells are connected in series, with each other. With such a configuration, a structure is obtained in which the photovoltaic cells adjacent in the direction of the slit S1 are electrically separated, and a plurality of photovoltaic cell groups, in each of which a plurality of photovoltaic cells are connected in series, are provided aligned with each other. The photovoltaic cell groups are finally connected in parallel to each other, to form the photovoltaic device 200.

In the separating groove 18, all of the transparent electrode 12, the photovoltaic unit 14, and the backside electrode 16 formed over the transparent substrate 10 are removed. The separating groove 18 maintains the electrical insulation between the outside and the panel at the panel periphery of the photovoltaic device 200.

The insulating groove 20 is formed at a more inward position in the panel than the separating groove 18. The insulating groove 20 is formed as a groove in which at least the backside electrode 16 is removed. By forming the insulating groove 20 in addition to the separating groove 18, it is possible to maintain a high electrical insulation between the peripheral portion and the more inward portion than the insulating groove 20, even when the electrical insulation between the outside and the panel due to the separating groove 18 is degraded.

In addition, because the backside electrode in a portion near the separating groove 18 and the backside electrode in the other portions can be insulated by the insulating groove 20, the cell regions on both sides of the insulating groove are electrically connected primarily by the transparent electrode. Because the transparent electrode is a transparent conductive film, the resistivity is higher compared to a metal. Therefore, in the integrated solar cell, influences of defects such as short-circuiting of a portion near the separating groove 18 can be reduced, and at the same time, electrical energy generated in the portion near the first insulting groove 18 can be extracted, resulting in an increased output.

In addition, the insulating groove 20 is formed as a groove in which at least the backside electrode 16 is removed. The slit S6 which becomes the insulating groove 20 can be formed using the same laser device as the device for the laser for forming the slits S4 and S5 in step S38. With this configuration, it is not necessary to separately provide a structure for forming the insulating groove 20, and there is another advantage that the manufacturing cost of the photovoltaic device 200 can be reduced.

In addition, a step for removing the outer periphery portion of the photovoltaic device 200 or the like may be provided after step S40. Alternatively, a step for forming a back sheet or a resin layer for protecting the surface of the photovoltaic device 200 may be provided after step S40. The back sheet and the resin layer function as a protective layer of the photovoltaic device 200.

What is claimed is:

1. A photovoltaic device, wherein
a plurality of photovoltaic cells, in which a first electrode, a power generation layer, and a second electrode are sequentially layered over a substrate, are connected in series, and
the photovoltaic device comprises ends of the power generation layer and the second electrode at a periphery of the photovoltaic device and extending in a direction of the series connection, and an insulating groove formed in a region near a insulating groove the ends and parallel to the ends and formed by leaving the first electrode and removing at least the second electrode.

2. The photovoltaic device according to claim 1, wherein
the end is formed with a separating groove in the direction of the series connection in which the first electrode, the power generation layer, and the second electrode are removed.

3. The photovoltaic device according to claim 2, wherein
the insulating groove is formed in a region within 100 mm from the separating groove.

4. The photovoltaic device according to claim 3, wherein
the insulating groove is formed in a region within 10 mm from the separating groove.

5. A method of manufacturing a photovoltaic device, comprising:
forming a plurality of photovoltaic cells, in which a first electrode, a power generation layer, and a second electrode are sequentially layered over a substrate, in series connection to each other,
forming a separating groove at a periphery of the photovoltaic device in a direction intersecting the direction of the series connection by removing the first electrode, the power generation layer, and the second electrode, and
forming an insulating groove in a region near the separating groove and parallel to the separating groove, by leaving the first electrode and removing at least the second electrode.
